(19) United States
(12) Patent Application Publication
(10) Pub. No.: US 2024/0355391 A1
(43) Pub. Date: Oct. 24, 2024

(54) Memory Circuitry Comprising Strings Of Memory Cells And Method Used In Forming Memory Circuitry Comprising Strings Of Memory Cells

(71) Applicant: Micron Technology, Inc., Boise, ID (US)

(72) Inventors: Pengyuan Zheng, Boise, ID (US); Matthew J. King, Boise, ID (US); Naveen Kaushik, Boise, ID (US); Ravi Jadhav, Sangli (IN); Sidhartha Gupta, Boise, ID (US)

(73) Assignee: Micron Technology, Inc., Boise, ID (US)

(21) Appl. No.: 18/618,930

(22) Filed: Mar. 27, 2024

Related U.S. Application Data
(60) Provisional application No. 63/461,373, filed on Apr. 24, 2023.

(51) Int. Cl. G11C 16/04; H01L 23/522; H01L 23/528; H10B 41/10; H10B 41/27; H10B 41/35; H10B 43/10; H10B 43/27; H10B 43/35

(52) U.S. Cl. CPC G11C 16/0483; H01L 23/5226; H01L 23/5283; H10B 41/10; H10B 41/27; H10B 41/35; H10B 43/10; H10B 43/27; H10B 43/35

(57) ABSTRACT

A method used in forming memory circuitry comprising strings of memory cells comprises forming vertically-alternating tiers of different composition first and second materials. The second material is insulative. The vertically-alternating tiers comprise a stack comprising laterally-spaced memory blocks. An inter-block column of openings is formed through the vertically-alternating tiers longitudinally-along and between immediately-laterally-adjacent of the memory blocks. An intra-block column of openings is formed through the vertically-alternating tiers longitudinally-along and within individual of the memory blocks. Individual of the intra-block columns of openings are entirely within one of the individual memory blocks. A first etchant is flowed into the inter-block columns of openings and into the intra-block columns of openings to etch the first material of the first-material tiers selectively relative to the second-material tiers to form a void-space tier vertically between immediately-vertically-adjacent of the second-material tiers. The void-space tiers are filled with conductive material by flowing the conductive material or one or more precursors thereof through the inter-block columns of openings and through the intra-block columns of openings into the void-space tiers. A second etchant is flowed into the inter-block columns of openings to remove the conductive material from being between the immediately-laterally-adjacent memory blocks in individual of the filled void-space tiers. Structures independent of method are disclosed.

### TECHNICAL FIELD

Embodiments disclosed herein pertain to memory circuitry comprising strings of memory cells and to methods used in forming memory circuitry comprising strings of memory cells.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

A field effect transistor is one type of electronic component that may be used in a memory cell. These transistors comprise a pair of conductive source/drain regions having a semiconductive channel region there-between. A conductive gate is adjacent the channel region and separated there-from by a thin gate insulator. Application of a suitable voltage to the gate allows current to flow from one of the source/drain regions to the other through the channel region. When the voltage is removed from the gate, current is largely prevented from flowing through the channel region. Field effect transistors may also include additional structure, for example a reversibly programmable charge-storage region as part of the gate construction between the gate insulator and the conductive gate.

Flash memory is one type of memory and has numerous uses in modern computers and devices. For instance, modern personal computers may have BIOS stored on a flash memory chip. As another example, it is becoming increasingly common for computers and other devices to utilize flash memory in solid state drives to replace conventional hard drives. As yet another example, flash memory is popular in wireless electronic devices because it enables manufacturers to support new communication protocols as they become standardized, and to provide the ability to remotely upgrade the devices for enhanced features.

NAND may be a basic architecture of integrated flash memory. A NAND cell unit comprises at least one selecting device coupled in series to a serial combination of memory cells (with the serial combination commonly being referred to as a NAND string). NAND architecture may be configured in a three-dimensional arrangement comprising vertically-stacked memory cells individually comprising a reversibly programmable vertical transistor. Control or other circuitry may be formed below the vertically-stacked memory cells. Other volatile or non-volatile memory array architectures may also comprise vertically-stacked memory cells that individually comprise a transistor.

Memory arrays may be arranged in memory pages, memory blocks and partial blocks (e.g., sub-blocks), and memory planes, for example as shown and described in any of U.S. Patent Application Publication Nos. 2015/0228651, 2016/0267984, and 2017/0140833. The memory blocks may at least in part define longitudinal outlines of individual wordlines in individual wordline tiers of vertically-stacked memory cells. Connections to these wordlines may occur in a so-called “stair-step structure” at an end or edge of an array of the vertically-stacked memory cells. The stair-step structure includes individual “stairs” (alternately termed “steps” or “stair-steps”) that define contact regions of the individual wordlines upon which elevationally-extending conductive vias contact to provide electrical access to the wordlines.

### BRIEF DESCRIPTION OF THE DRAWINGS

FIGS. 1-5 are diagrammatic cross-sectional views of portions of a construction that will comprise an array of elevationally-extending strings of memory cells in accordance with an embodiment of the invention.

FIGS. 6-46 are diagrammatic sequential sectional and/or enlarged views of the construction of FIGS. 1-5, or portions thereof or alternate and/or additional embodiments, in process in accordance with some embodiments of the invention.

### DETAILED DESCRIPTION OF EXAMPLE EMBODIMENTS

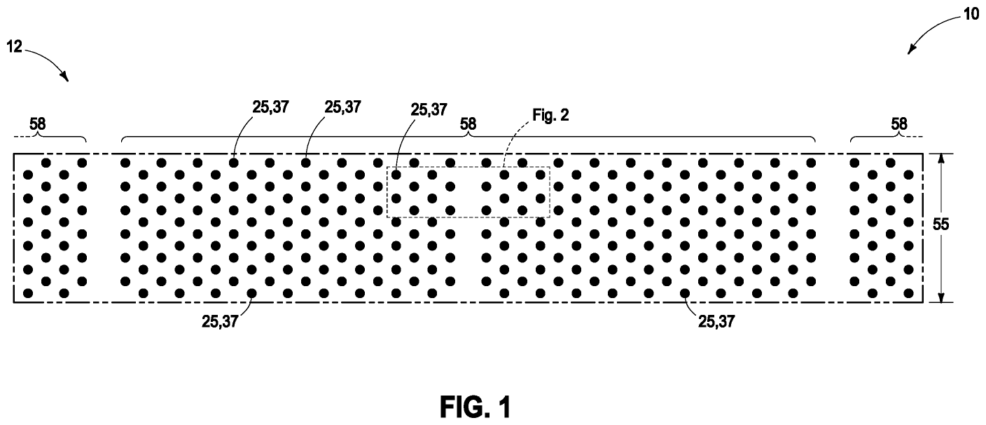

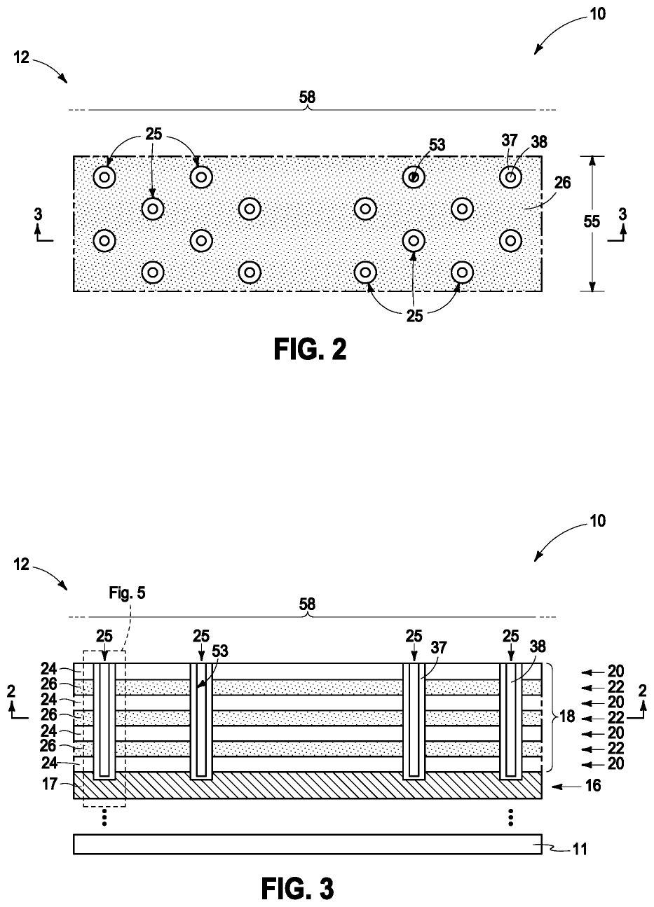

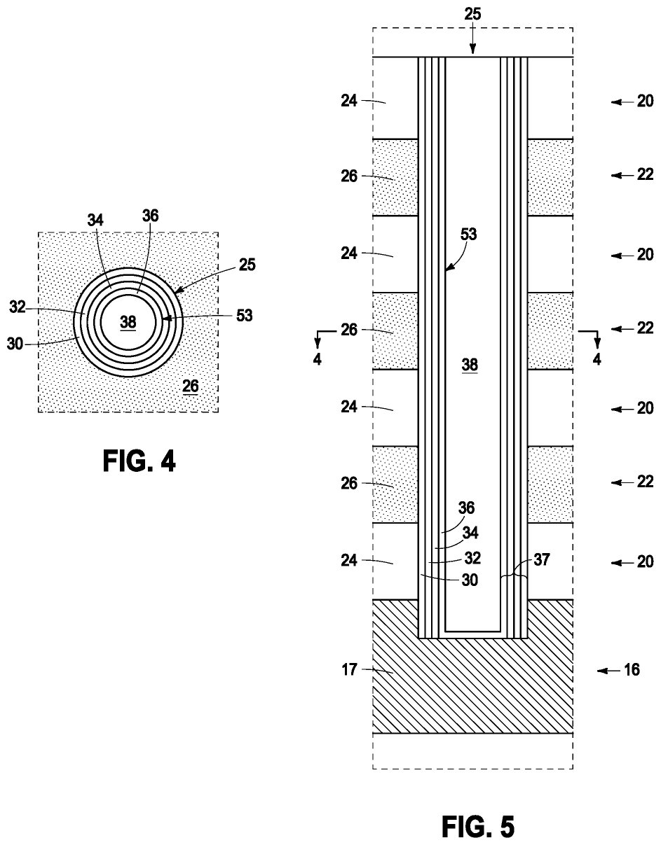

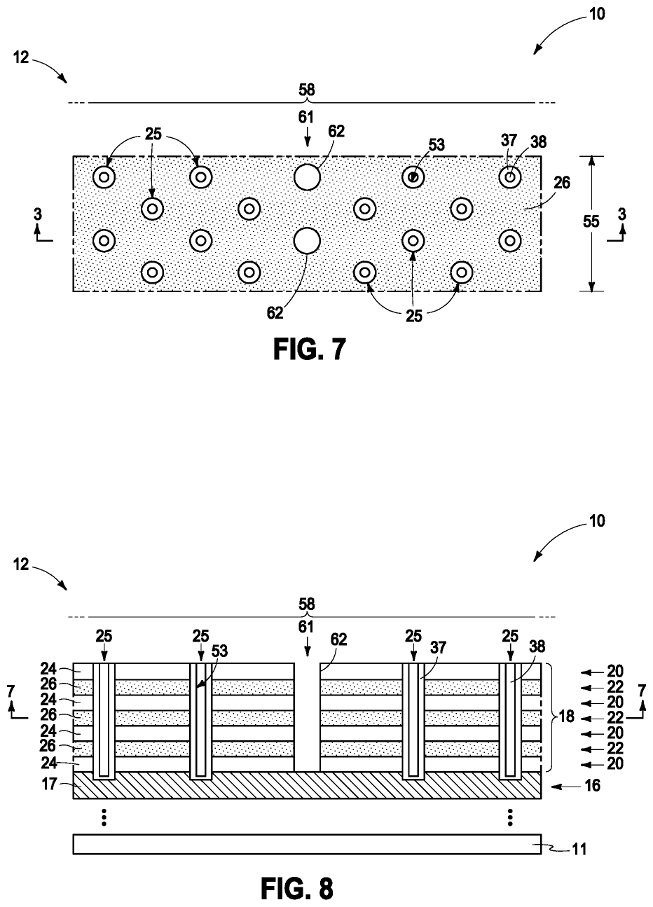

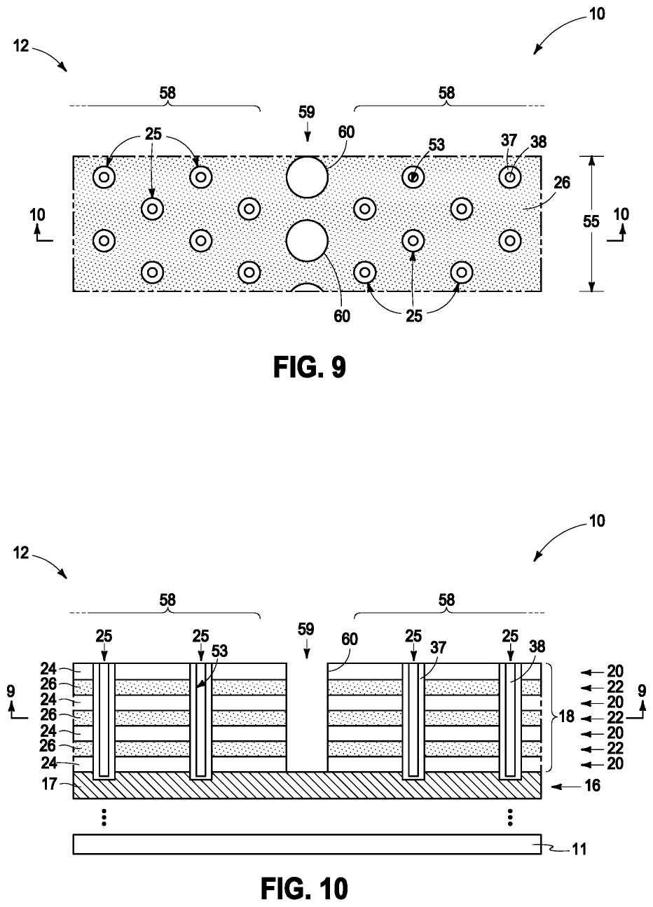

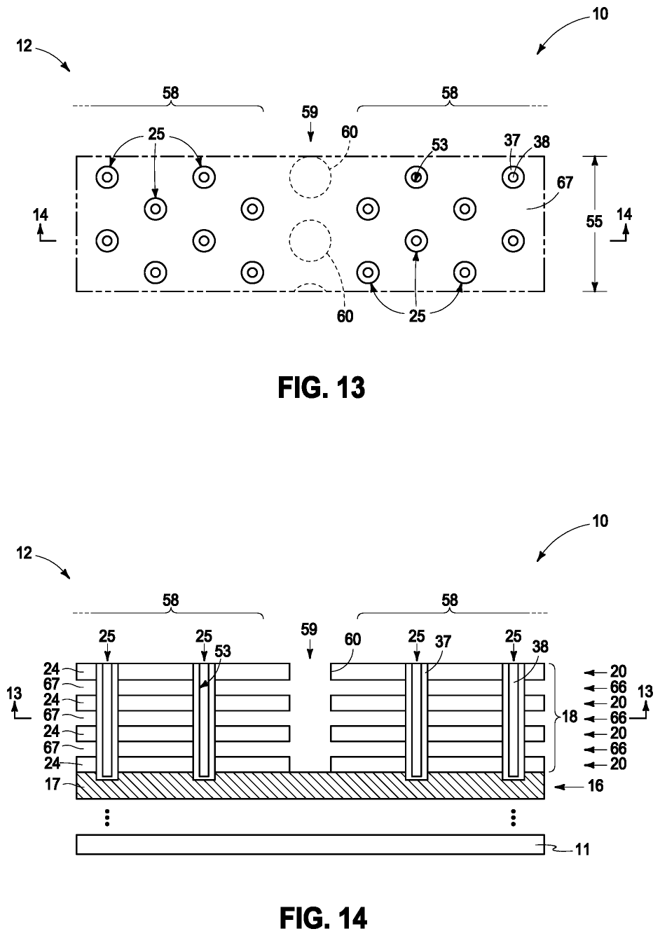

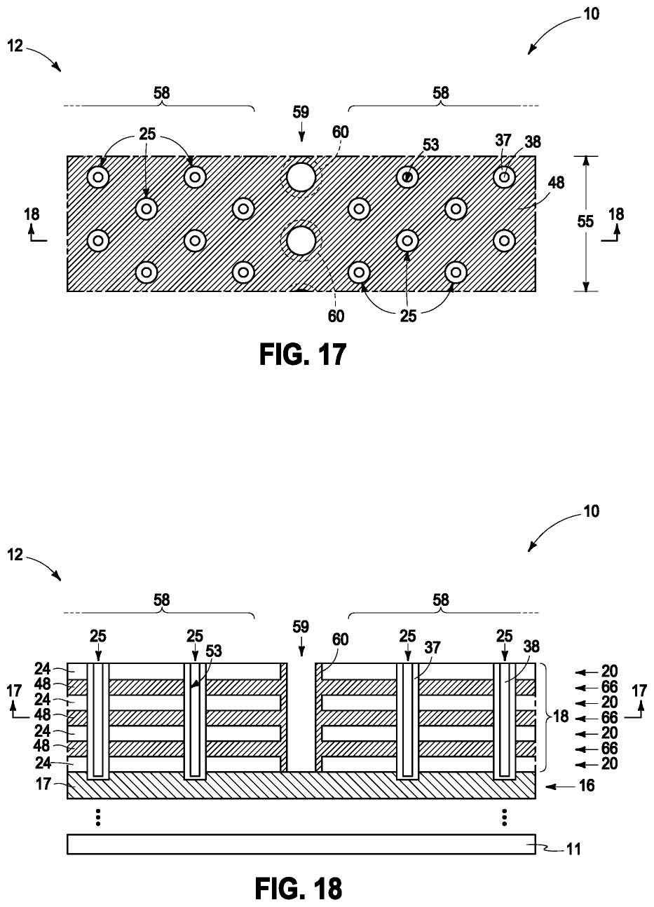

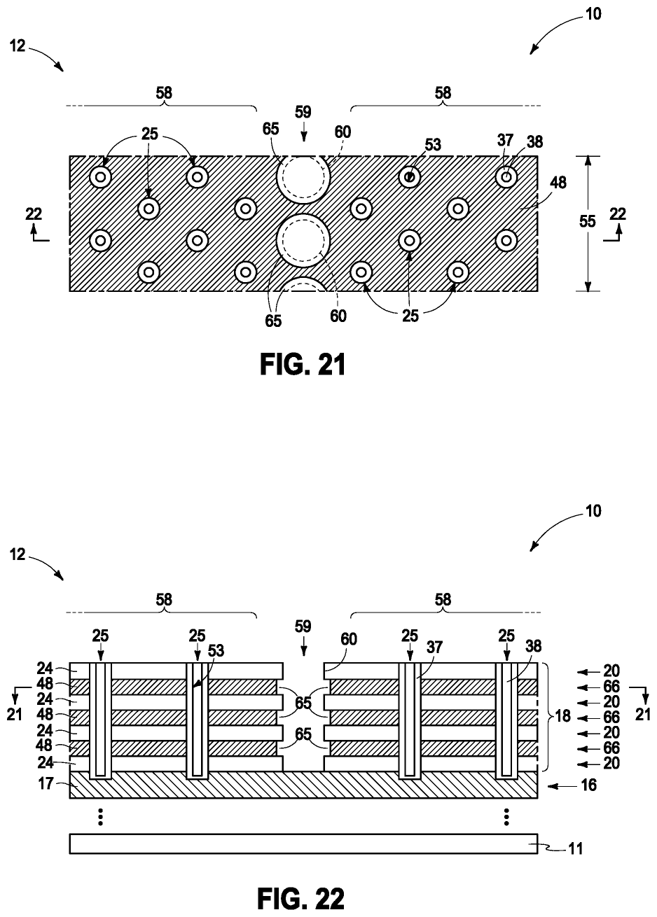

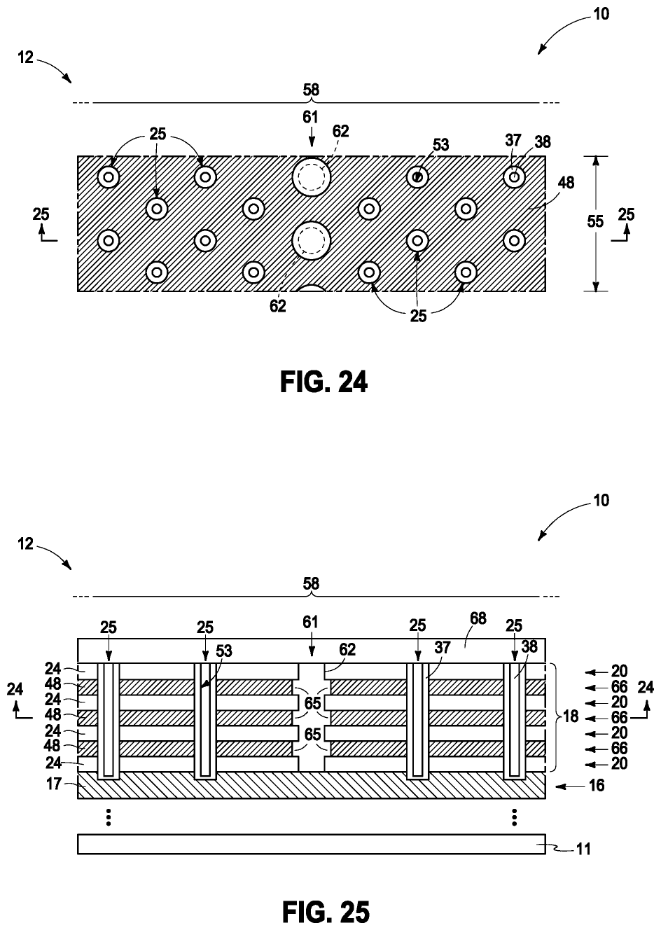

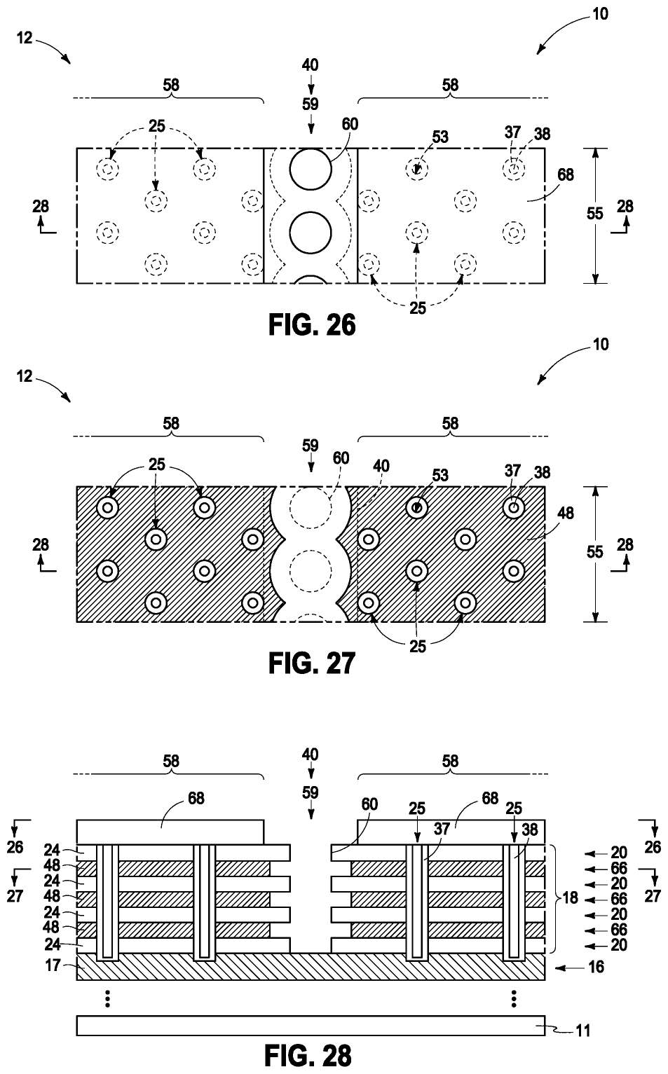

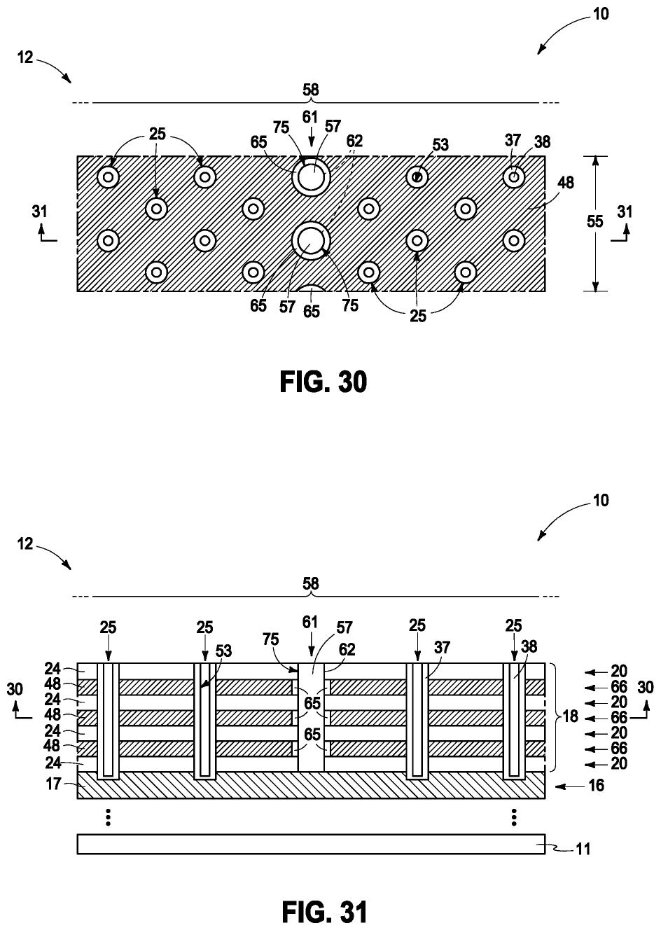

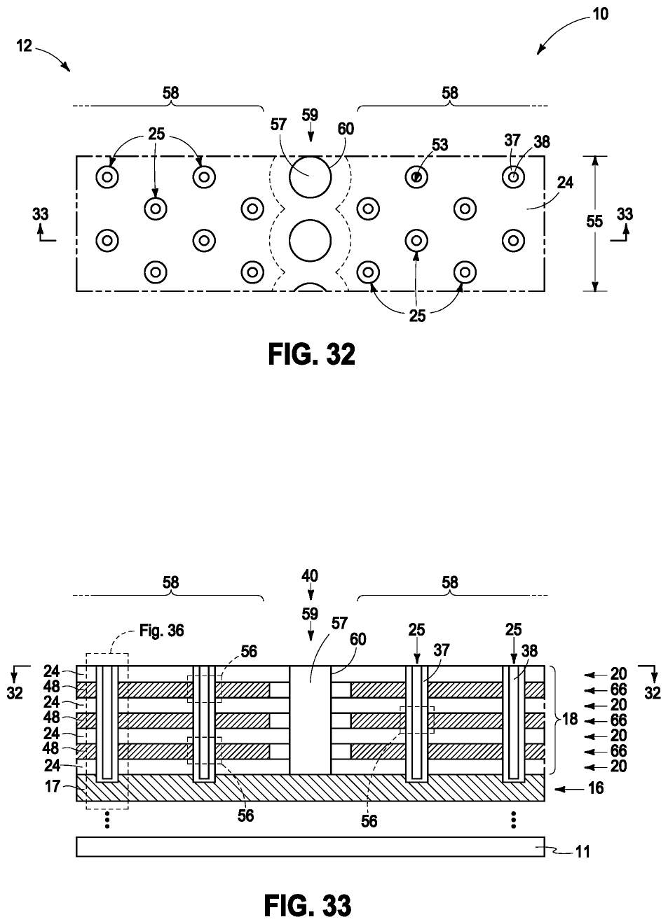

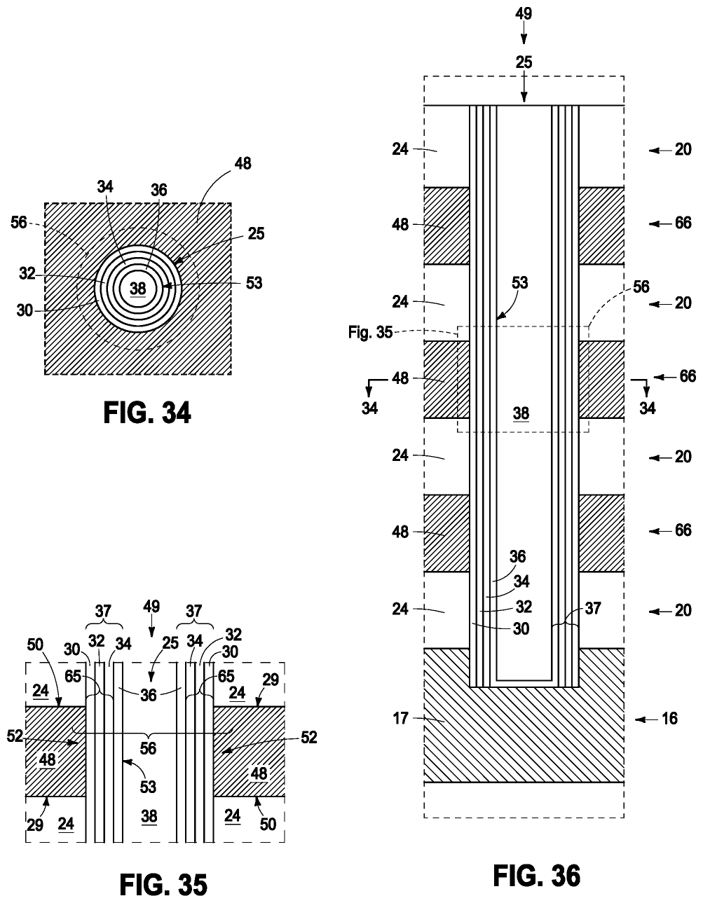

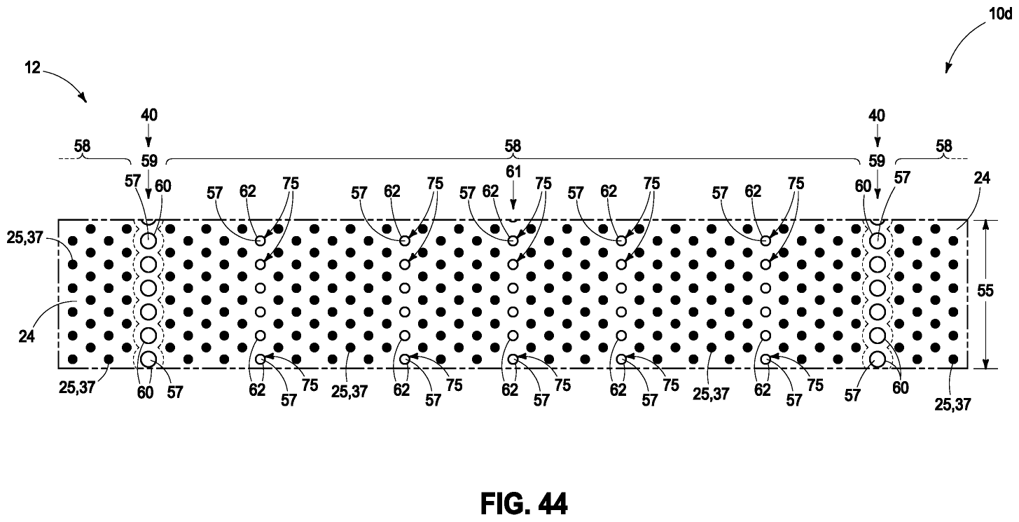

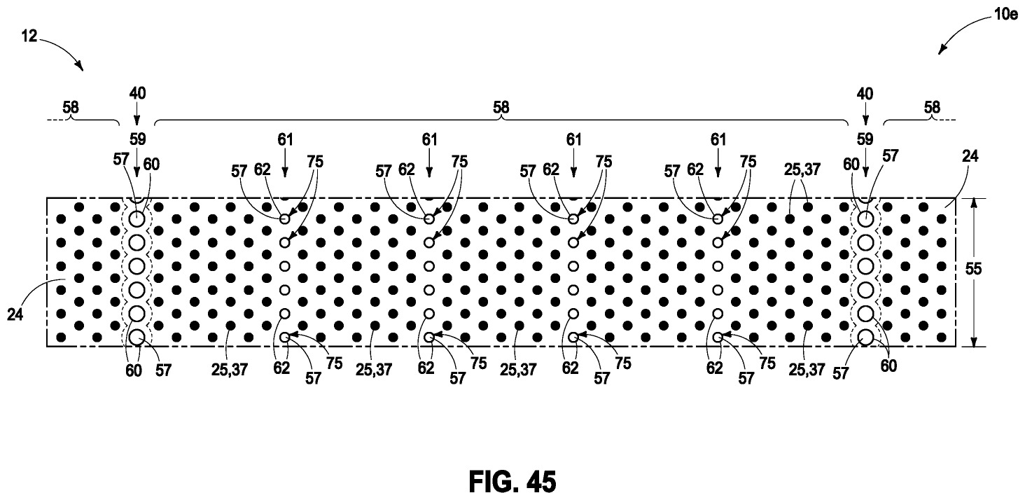

Embodiments of the invention encompass methods used in forming a memory array, for example an array of NAND or other memory cells that may have at least some peripheral control circuitry under the array (e.g., CMOS-under-array). Embodiments of the invention also encompass memory circuitry comprising strings of memory cells (e.g., NAND architecture) independent of method of manufacture. Example embodiments are described with reference to FIGS. 1-46.

FIGS. 1-5 show an example construction 10 having an array 12 in which elevationally-extending strings of transistors and/or memory cells will be formed. Such includes a base substrate 11 having any one or more of conductive/conductor/conducting, semiconductive/semiconductor/semiconducting, or insulative/insulator/insulating (i.e., electrically herein) materials. Various materials have been formed elevationally over base substrate 11. Materials may be aside, elevationally inward, or elevationally outward of the FIGS. 1-5-depicted materials. For example, other partially or wholly fabricated components of integrated circuitry may be provided somewhere above, about, or within base substrate 11. Control and/or other peripheral circuitry for operating components within an array (e.g., array 12) of elevationally-extending strings of memory cells may also be fabricated and may or may not be wholly or partially within an array or sub-array. Further, multiple sub-arrays may also be fabricated and operated independently, in tandem, or otherwise relative one another. In this document, a “sub-array” may also be considered as an array.

A conductor tier 16 comprising conductor material 17 (e.g., WSiₓ under conductively-doped polysilicon) is above substrate 11. Conductor tier 16 may comprise part of control circuitry (e.g., peripheral-under-array circuitry and/or a common source line or plate) used to control read and write access to the transistors and/or memory cells in array 12. Vertically-alternating tiers 22, 20 of different composition first and second materials 26, 24, respectively, have been formed above example conductor tier 16. Second material 24 is insulative (e.g., silicon dioxide). Example first materials 26 where second material 24 comprises silicon dioxide are silicon nitride and polysilicon. Example thickness for each of second-material tiers 20 and first-material tiers 22 is 20 to 60 nanometers. The example uppermost second-material tier 20 may be thicker/thickest compared to one or more other tiers 20 and/or 22. Only a small number of tiers 20 and 22 is shown in FIGS. 1-5, with more likely stack 18 comprising dozens, a hundred or more, etc. of tiers 20 and 22. Other circuitry that may or may not be part of peripheral and/or control circuitry may be between conductor tier 16 and stack 18. For example, multiple vertically-alternating tiers of conductive material and insulative material of such circuitry may be below a lowest of first-material tiers 22 and/or above an uppermost of first-material tiers 22. For example, one or more select gate tiers (not shown) may be between conductor tier 16 and the lowest first-material tier 22. Alternately or additionally, at least one of the depicted lowest first-material tiers 22 may be a select gate tier. Vertically-alternating tiers 20, 22 comprise a stack 18 comprising laterally-spaced memory blocks 58. Memory blocks 58 may be considered as being longitudinally elongated and oriented, for example along a first direction 55. Only one full memory block 58 is shown due to scale.

Channel openings 25 have been formed (e.g., by etching) through vertically-alternating tiers 20 and 22 to conductor tier 16. Channel openings 25 may taper radially-inward and/or radially-outward (not shown) moving deeper in stack 18. In some embodiments, channel openings 25 may go into conductor material 17 of conductor tier 16 as shown or may stop there-atop (not shown). Alternately, as an example, channel openings 25 may stop atop or within the lowest second-material tier 20. A reason for extending channel openings 25 at least to conductor material 17 of conductor tier 16 is to assure direct electrical coupling of channel material to conductor tier 16 without using alternative processing and structure to do so when such a connection is desired and/or to provide an anchoring effect to material that is within channel openings 25. Etch-stop material (not shown) may be within or atop conductor material 17 of conductor tier 16 to facilitate stopping of the etching of channel openings 25 relative to conductor tier 16 when such is desired. Such etch-stop material may be sacrificial or non-sacrificial. By way of example and for brevity only, channel openings 25 are shown as being arranged in groups or columns of staggered rows of twenty and eighteen openings 25 per row in laterally-spaced memory blocks 58. Only one full memory block 58 is shown due to scale. Any alternate arrangement and construction may be used.

Transistor channel material may be formed in the individual channel openings elevationally along the insulative tiers and the conductive tiers, thus comprising individual channel-material strings, which is directly electrically coupled with conductive material in the conductor tier. Individual memory cells of the example memory array being formed may comprise a gate region (e.g., a control-gate region) and a memory structure laterally between the gate region and the channel material. In one such embodiment, the memory structure is formed to comprise a charge-blocking region, storage material (e.g., charge-storage material), and an insulative charge-passage material. The storage material (e.g., floating gate material such as doped or undoped silicon or charge-trapping material such as silicon nitride, metal dots, etc.) of the individual memory cells is elevationally along individual of the charge-blocking regions. The insulative charge-passage material (e.g., a band gap-engineered structure having nitrogen-containing material [e.g., silicon nitride] sandwiched between two insulator oxides [e.g., silicon dioxide]) is laterally between the channel material and the storage material.

The figures show one embodiment wherein charge-blocking material 30, storage material 32, and charge-passage material 34 have been formed in individual channel openings 25 elevationally along vertically-alternating tiers 20 and 22. Transistor materials 30, 32, and 34 (e.g., memory-cell materials) may be formed by, for example, deposition of respective thin layers thereof over stack 18 and within individual channel openings 25 followed by planarizing such back at least to a top surface of stack 18 as shown.

Channel material 36 has also been formed in channel openings 25 elevationally along vertically-alternating tiers 20 and 22 and comprises individual channel-material strings 53 in one embodiment having memory-cell materials (e.g., 30, 32, and 34) there-along and with second material 24 in second-material tiers 20 being horizontally-between immediately-adjacent channel-material strings 53. Materials 30, 32, 34, and 36 are collectively shown as and only designated as material 37 in some figures due to scale. Example channel materials 36 include appropriately-doped crystalline semiconductor material, such as one or more silicon, germanium, and so-called III/V semiconductor materials (e.g., GaAs, InP, GaP, and GaN). Example thickness for each of materials 30, 32, 34, and 36 is 25 to 100 Angstroms. Punch etching may be conducted as shown to remove materials 30, 32, and 34 from the bases of channel openings 25 to expose conductor tier 16 such that channel material 36 (channel-material string 53) is directly electrically coupled with conductor material 17 of conductor tier 16. Such punch etching may occur separately with respect to each of materials 30, 32, and 34 (as shown) or may occur collectively with respect to all after deposition of material 34 (not shown). Alternately, and by way of example only, no punch etching may be conducted and channel material 36 may be directly electrically coupled with conductor material 17 of conductor tier 16 by a separate conductive interconnect (not shown). Channel openings 25 are shown as comprising a radially-central solid dielectric material 38 (e.g., spin-on-dielectric, silicon dioxide, and/or silicon nitride). Alternately, and by way of example only, the radially-central portion within channel openings 25 may include void space(s) (not shown) and/or be devoid of solid material (not shown).

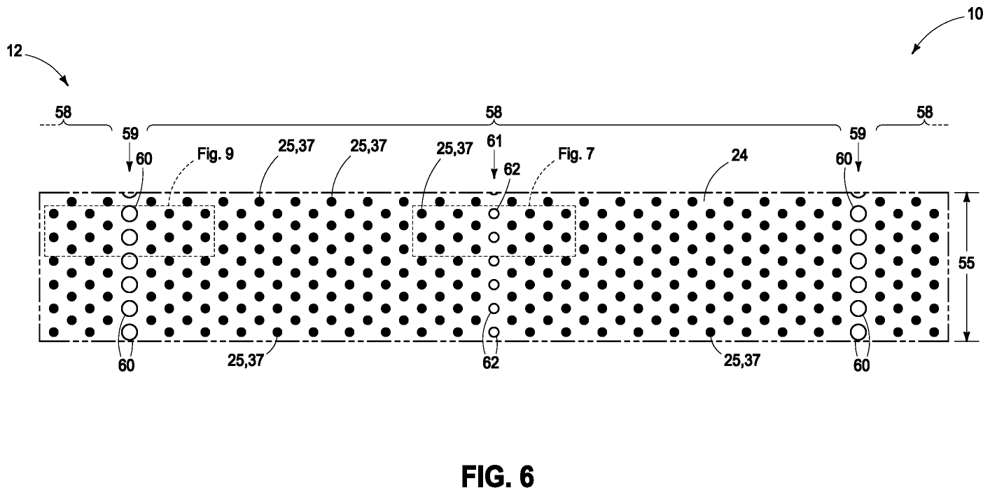

Referring to FIGS. 6-10, an inter-block column 59 of openings 60 has been formed through vertically-alternating tiers 20, 22 longitudinally-along and between immediately-laterally-adjacent of memory blocks 58. An intra-block column 61 of openings 62 has been formed through vertically-alternating tiers 20, 22 longitudinally-along and within individual memory blocks 58. Individual of intra-block columns 61 of openings 62 are entirely within one of individual memory blocks 58. In one embodiment, inter-block column 59 of openings 60 and intra-block columns 61 of openings 62 are formed simultaneously and in another embodiment are formed at different times relative one another (either being formed before or after the other). Openings 60 and openings 62 may be of the same size relative one another or may be of different sizes relative one another. Openings 60 and/or openings 62 may taper inwardly and/or outwardly along their respective lengths. Openings 60 may be of the same or different sizes relative one another. Openings 62 may be of the same or different sizes relative one another. Openings 60 and/or openings 62 may be of the same size as channel openings 25. Openings 60 and/or openings 62 may be formed before or after forming channel openings 25 and, regardless may be formed before or after forming example materials 30, 32, 34, 36, and/or 38 in channel openings 25 (e.g., openings 25, 60, and 62 may be formed at the same time, openings 60 and 62 plugged with a sacrificial material [not shown] while openings 25 are filled with example materials 30, 32, 34, 36, and/or 38, followed by removal of such sacrificial material before use of a first etchant referred to below). Regardless, in one embodiment and as shown, intra-block columns 61 of openings 62 are formed to be laterally-centered within individual memory blocks 58.

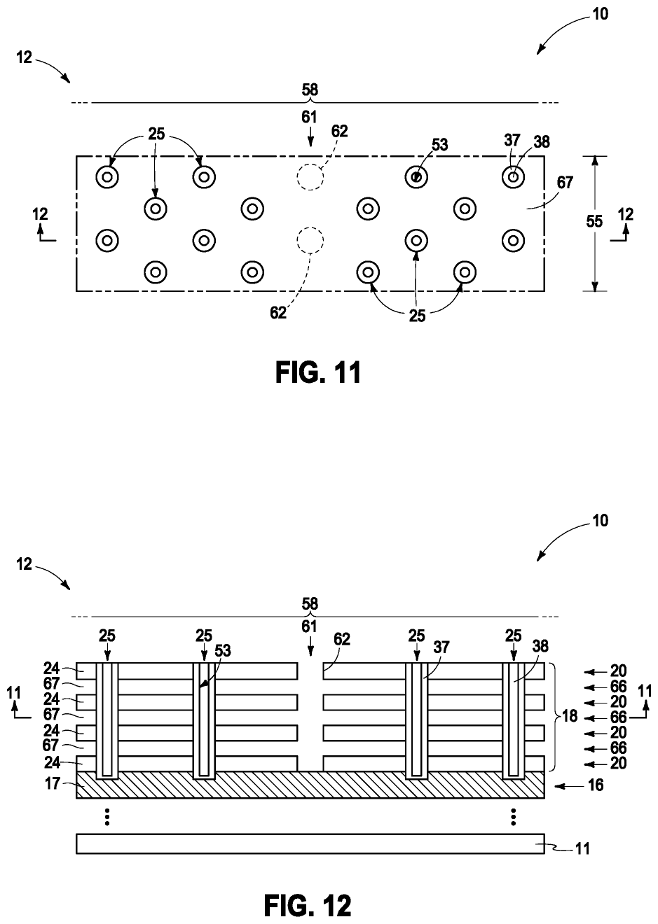

Referring to FIGS. 11-14, a first etchant has been flowed into inter-block columns 59 of openings 60 and into the intra-block columns 61 of openings 62 to etch first material 26 (no longer shown) of first-material tiers 22 (no longer shown/so-designated) selectively relative to second-material tiers 20 to form a void-space tier 66 (e.g., comprising void-space 67) vertically between immediately-vertically-adjacent of second-material tiers 20. An example first etchant where first material 26 comprises silicon nitride and second material 24 comprises silicon dioxide is H₃PO₄. An example first etchant where first material 26 comprises polysilicon and second material 24 comprises silicon dioxide is tetramethylammonium hydroxide.

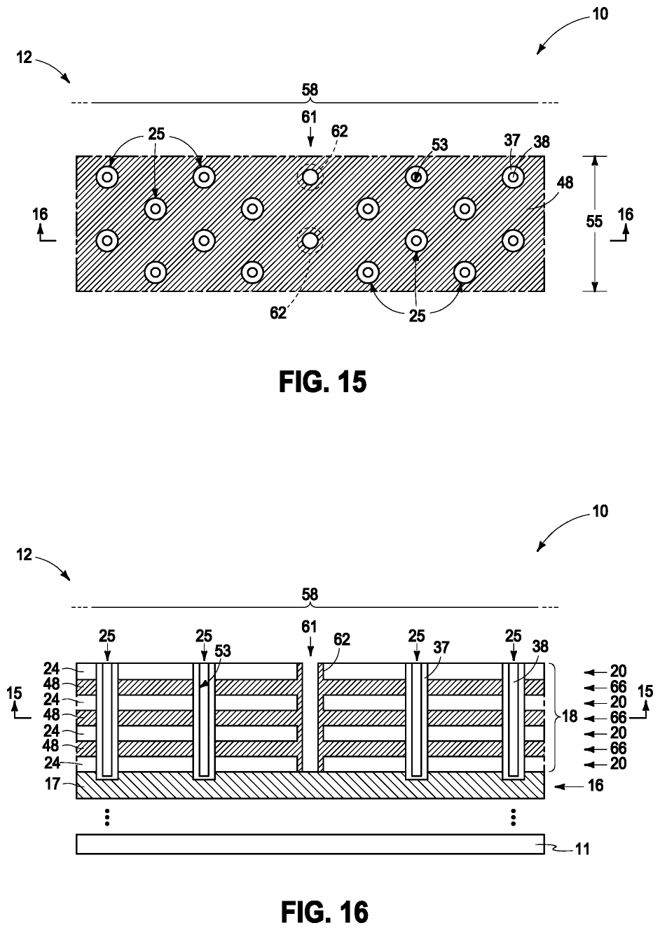

Referring to FIGS. 15-18, void-space tiers 66 have been filled (e.g., ideally completely) with conductive material 48 (e.g., conductive metal material such as TiN and W) by flowing conductive material 48 or one or more precursors thereof through inter-block columns 59 of openings 60 and through intra-block columns 61 of openings 62 into void-space tiers 66. At the conclusion of forming conductive material 48, such may completely fill openings 60 and/or 62 (not shown) or line and less-than-fill openings 60 and/or 62 (as shown). Channel-material strings 53 may be formed before or after forming conductive material 48. If after, conductive material 48 or one or more precursors thereof may also be flowed through channel openings 25 (if existing at this point of processing). Alternately, by way of example, channel openings 25 (if existing at this point of processing) could be filled with sacrificial material (not shown) first, and be so-filled while conductive material 48 or one or more precursors thereof is flowed through openings 60 and openings 62.

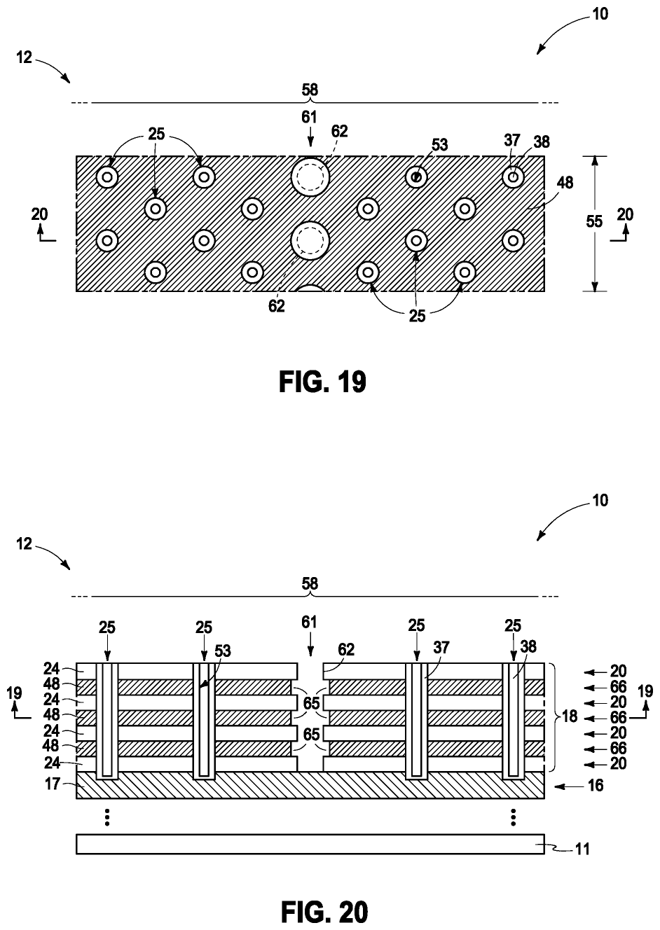

Referring to FIGS. 19-22, conductive material 48 has been removed from openings 60 and openings 62 (e.g., by isotropic etching). In one embodiment and as shown, a degree of over-etch has occurred relative to void-space tiers 66 such that an annular void-space 65 is formed circumferentially around openings 60 and 62 in individual of void-space tiers 66 (e.g., to better assure that conductive material 48 in different void-space tiers 66 is not shorted together). The artisan is capable of selecting a suitable etchant to achieve the example depicted construction depending on the composition(s) of conductive material 48 and the composition(s) of second material 24.

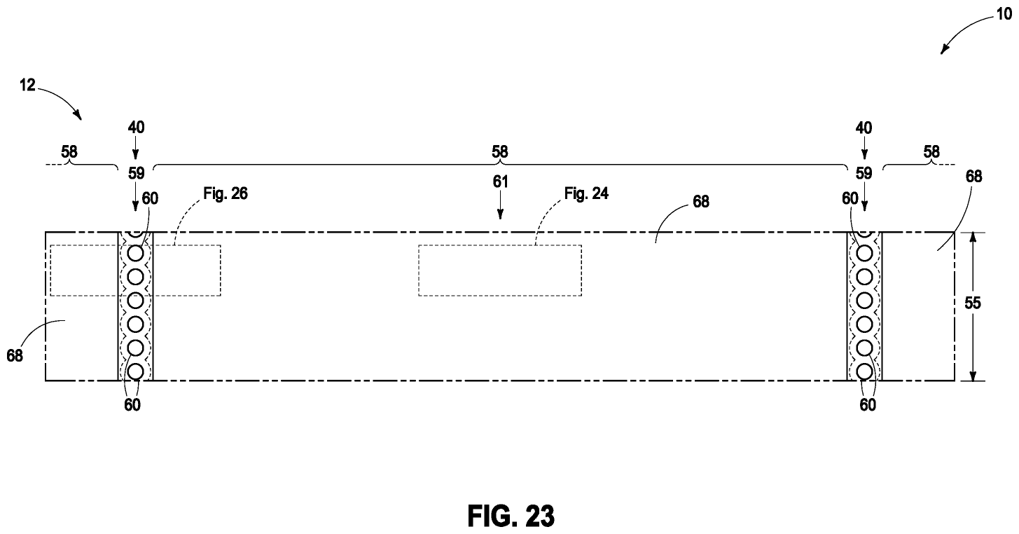

Referring to FIGS. 23-28, a second etchant has been flowed into inter-block columns 59 of openings 60 to remove conductive material 48 from being between immediately-laterally-adjacent memory blocks 58 in individual of filled void-space tiers 66. In one embodiment and ideally, intra-block columns 61 of openings 62 are completely masked (e.g., by masking material 68 [e.g., silicon dioxide] having trenches 40 formed therethrough) while flowing the second etchant into inter-block columns 59 of openings 60 to preclude the second etchant from flowing in intra-block columns 61 of openings 62. Again, the artisan is capable of selecting a suitable second etchant to achieve the example depicted construction depending on the composition(s) of conductive material 48 and the composition(s) of second material 24 (e.g., which may be the same as used in the example etching of FIGS. 19-22).

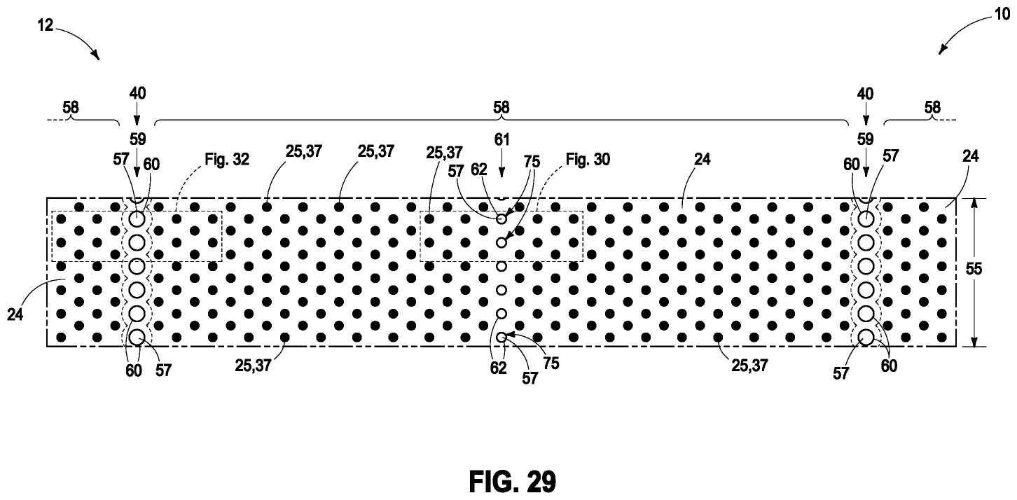

Referring to FIGS. 29-36, and in one embodiment, example masking material 68 (not shown) has been removed and openings 60 and 62 have been filled with insulating material 57 (e.g., which may be of the same or different composition as that of second material 24). Insulating material 57 along with second material 24 provide lateral electrical isolation (insulation) between immediately-laterally-adjacent memory blocks. In one embodiment and as shown, annular void-spaces 65 remain in intra-block columns 61 (e.g., around insulating material 57; e.g., and some void-space may remain in inter-block columns 59 as shown). Further, in one embodiment, insulating material 57 may be considered as forming or comprising an intra-block column 61 of structures 75 (e.g., individually comprising an insulative pillar) extending through vertically-alternating tiers 20, 66 longitudinally-along and within individual memory blocks 58, with an annular void-space 65 being circumferentially around individual of structures 75 in individual of now-conductive tiers 66.

Conductive material 48 forms individual conductive lines 29 (e.g., wordlines in stack 18) and elevationally-extending strings 49 of individual transistors and/or memory cells 56 in stack 18. A thin insulative liner (e.g., Al₂O₃ and not shown) may be formed before forming conductive material 48. Approximate locations of transistors and/or memory cells 56 are indicated with a bracket in some figures and some with dashed outlines in some figures, with transistors and/or memory cells 56 being essentially ring-like or annular in the depicted example. Alternately, transistors and/or memory cells 56 may not be completely encircling relative to individual channel openings 25 such that each channel opening 25 may have two or more elevationally-extending strings 49 (e.g., multiple transistors and/or memory cells about individual channel openings in individual conductive tiers with perhaps multiple wordlines per channel opening in individual conductive tiers, and not shown). Conductive material 48 may be considered as having terminal ends 50 corresponding to control-gate regions 52 of individual transistors and/or memory cells 56. Control-gate regions 52 in the depicted embodiment comprise individual portions of individual conductive lines 29. Materials 30, 32, and 34 may be considered as a memory structure 65 that is laterally between control-gate region 52 and channel material 36.

A charge-blocking region (e.g., charge-blocking material 30) is between storage material 32 and individual control-gate regions 52. A charge block may have the following functions in a memory cell: In a program mode, the charge block may prevent charge carriers from passing out of the storage material (e.g., floating-gate material, charge-trapping material, etc.) toward the control gate, and in an erase mode the charge block may prevent charge carriers from flowing into the storage material from the control gate. Accordingly, a charge block may function to block charge migration between the control-gate region and the storage material of individual memory cells. An example charge-blocking region as shown comprises insulator material 30. By way of further examples, a charge-blocking region may comprise a laterally (e.g., radially) outer portion of the storage material (e.g., material 32) where such storage material is insulative (e.g., in the absence of any different-composition material between an insulative storage material 32 and conductive material 48). Regardless, as an additional example, an interface of a storage material and conductive material of a control gate may be sufficient to function as a charge-blocking region in the absence of any separate-composition-insulator material 30. Further, an interface of conductive material 48 with material 30 (when present) in combination with insulator material 30 may together function as a charge-blocking region, and as alternately or additionally may a laterally-outer region of an insulative storage material (e.g., a silicon nitride material 32). An example material 30 is one or more of silicon hafnium oxide and silicon dioxide.

Any other attribute(s) or aspect(s) as shown and/or described herein with respect to other embodiments may be used in the embodiments shown and described with reference to the above embodiments.

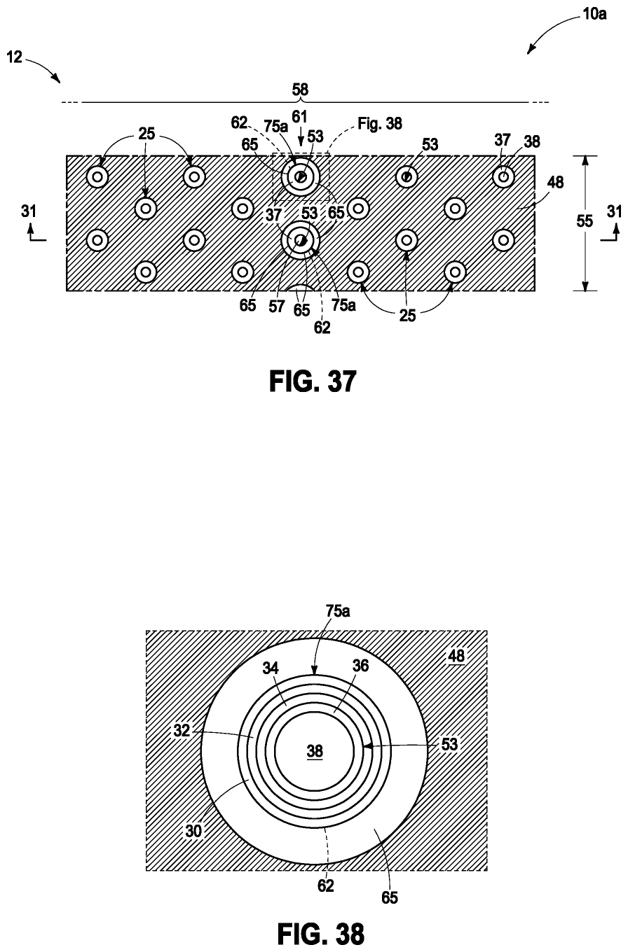

An alternate example resultant construction 10a is shown in FIGS. 37-40. Like numerals from the above-described embodiments have been used where appropriate, with some construction differences being indicated with the suffix “a” or with different numerals. Structures 75a in construction 10a individually comprise a dummy channel-material string 53 (e.g., regardless of when formed; e.g., structures 75a also comprising materials 30, 32, 34, and 38 in one embodiment). Further, regardless, and in one embodiment, construction 10a comprises an inter-block column 59 of dummy channel-material strings 53 extending through stack 18 longitudinally-along and between immediately-laterally-adjacent memory blocks 58 (e.g., regardless of when formed; e.g., structures in inter-block column 59 also comprising materials 30, 32, 34, and 38 in one embodiment). Herein, something is “dummy” if it is circuit-inoperative meaning no current flow there-through even if the something is conductive and which may be a circuit inoperable dead end that is not part of a current flow path of a circuit even if extending to or from an electronic component. Any other attribute(s) or aspect(s) as shown and/or described herein with respect to other embodiments may be used.

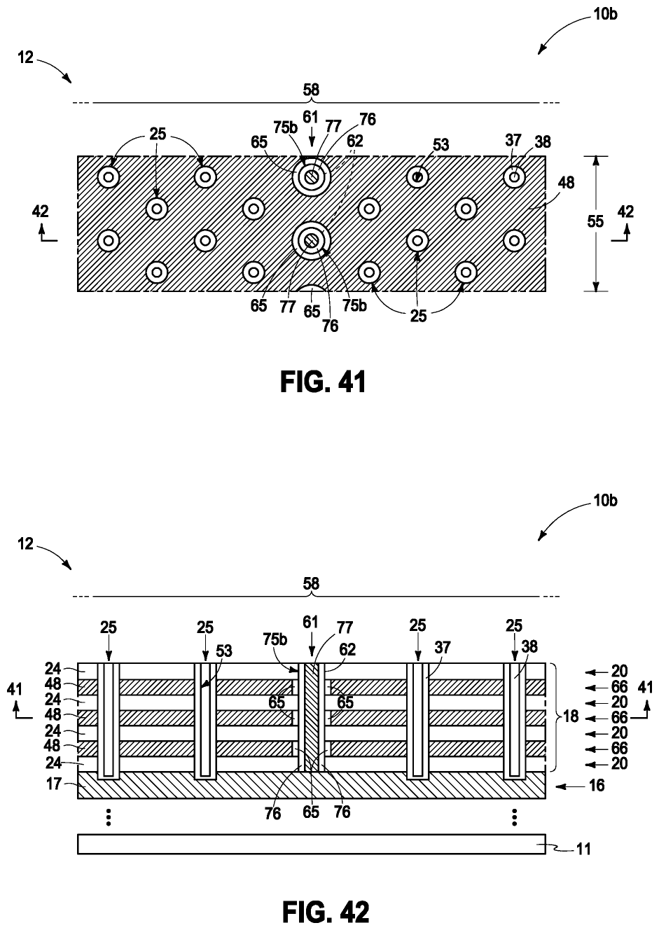

An alternate example resultant construction 10b is shown in FIGS. 41 and 42. Like numerals from the above-described embodiments have been used where appropriate, with some construction differences being indicated with the suffix “b” or with different numerals. Structures 75b in construction 10b individually comprise an insulative cylinder 76 surrounding a conductive-material core 77. In one such embodiment, structures 75b individually comprise a dummy through-array-via and in another such embodiment comprise an operative through-array-via. Analogous structures may be formed in inter-block columns 59 (not shown). Any other attribute(s) or aspect(s) as shown and/or described herein with respect to other embodiments may be used.

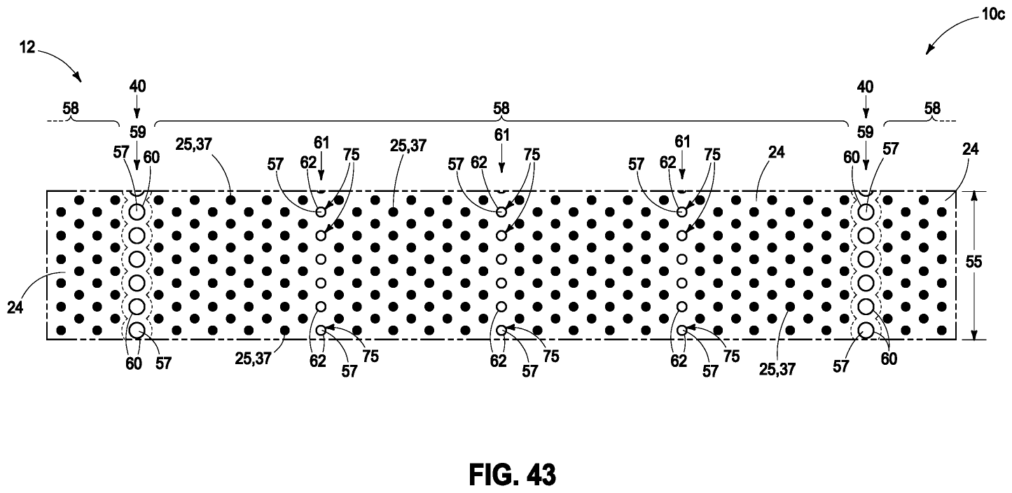

FIGS. 1-36 show an example embodiment having one (e.g., only one) intra-block column 61 of openings 62 within individual memory blocks 58. Alternately, multiple intra-block columns of openings may be formed through the vertically-alternating tiers longitudinally-along and within the individual memory blocks. In such event, the first etchant is flowed into the multiple intra-block columns of openings within the individual memory blocks to etch the first material of the first-material tiers selectively relative to the second-material tiers to form the void-space tier vertically between the immediately-vertically-adjacent second-material tiers. Further, the void-space tiers are filled with the conductive material by flowing the conductive material or one or more precursors thereof through the multiple intra-block columns of openings within the individual memory blocks into the void-space tiers. By way of examples only, FIGS. 43, 44, and 45 show example such constructions 10c, 10d, and 10e, respectively. Like numerals from the above-described embodiments have been used where appropriate, with some construction differences being indicated with the suffixes “c”, “d”, and “e”, respectively. In one embodiment, one of the multiple intra-block columns of openings within the individual memory blocks is laterally-centered therein (e.g., as in constructions 10, 10c, and 10d). In one embodiment, none of the multiple intra-block columns of openings within the individual memory blocks is laterally-centered therein (e.g., as in construction 10e). Any other attribute(s) or aspect(s) as shown and/or described herein with respect to other embodiments may be used.

FIGS. 29 and 43-45 also show example embodiments having one (e.g., only one) inter-block column 59 of openings 60 longitudinally-along and between immediately-laterally-adjacent of memory blocks 58. Alternately, multiple inter-block columns of openings may be longitudinally-along and between immediately-laterally-adjacent memory blocks (not shown). Any other attribute(s) or aspect(s) as shown and/or described herein with respect to other embodiments may be used.

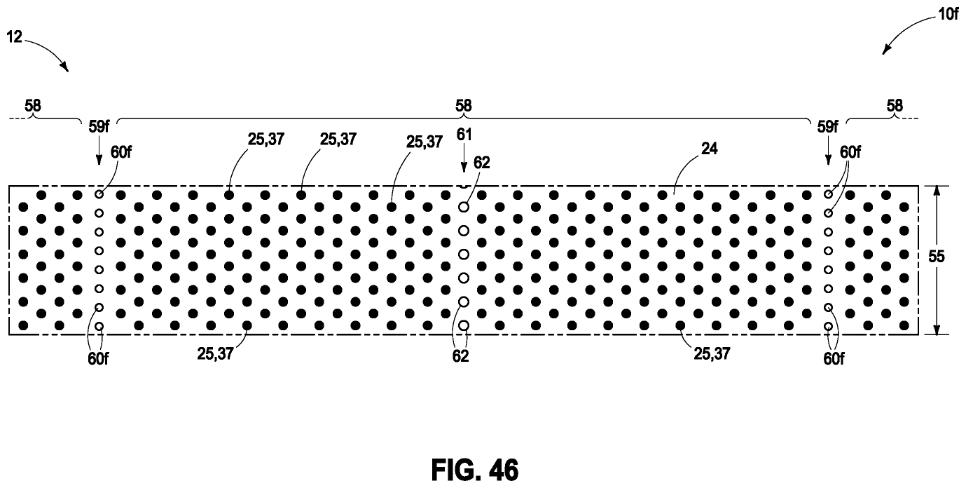

FIG. 46 shows an alternate embodiment construction 10f corresponding to that of FIG. 6 and construction 10. Like numerals from the above-described embodiments have been used where appropriate, with some construction differences being indicated with the suffix “f” or with different numerals. By way of example only, construction 10f in FIG. 46 comprises openings 60f in individual inter-block columns 59f that are greater in number than in individual inter-block columns 59 in construction 10 in FIG. 6. Any other attribute(s) or aspect(s) as shown and/or described herein with respect to other embodiments may be used.

In the example depicted constructions 10a-10f, openings 60 and 62 (where shown) have ultimately been filled (e.g., completely) with the same material(s). Alternately, openings 60 and 62 may be filled with different material(s).

As memory blocks in prior art constructions have become wider, in replacement gate processing, it can be difficult to completely fill the conductive tiers with conductive material, thus leaving some adverse void-space therein. Providing one or more intra-block columns of openings through which the conductive material or precursors thereof can flow can reduce or eliminate formation of such adverse-void space. Space that might be taken up by such intra-block column(s) of openings might be compensated for by forming an inter-block column of openings instead of an initially-formed horizontal trench between blocks that may enable immediately-laterally-adjacent blocks to be formed closer together.

Alternate embodiment constructions may result from method embodiments described above, or otherwise. Regardless, embodiments of the invention encompass memory arrays independent of method of manufacture. Nevertheless, such memory arrays may have any of the attributes as described herein in method embodiments. Likewise, the above-described method embodiments may incorporate, form, and/or have any of the attributes described with respect to device embodiments.

In one embodiment, a memory array (e.g., 12) comprising strings (e.g., 49) of memory cells (e.g., 56) comprises laterally-spaced memory blocks (e.g., 58) individually comprising a vertical stack (e.g., 18) comprising alternating insulative tiers (e.g., 20) and conductive tiers (e.g., 66). Operative channel-material strings (e.g., 53) of memory cells (e.g., 56) extend through the insulative tiers and the conductive tiers in individual of the memory blocks. An intra-block column (e.g., 59) of structures (e.g., 75*; an * being used as a suffix to be inclusive of all such same-numerically-designated structures or portions thereof that may or may not have other suffixes) extend through the vertically-alternating tiers longitudinally-along and within the individual memory blocks. An annular void-space (e.g., 65) is circumferentially around individual of the structures in individual of the conductive tiers. Any other attribute(s) or aspect(s) as shown and/or described herein with respect to other embodiments may be used.

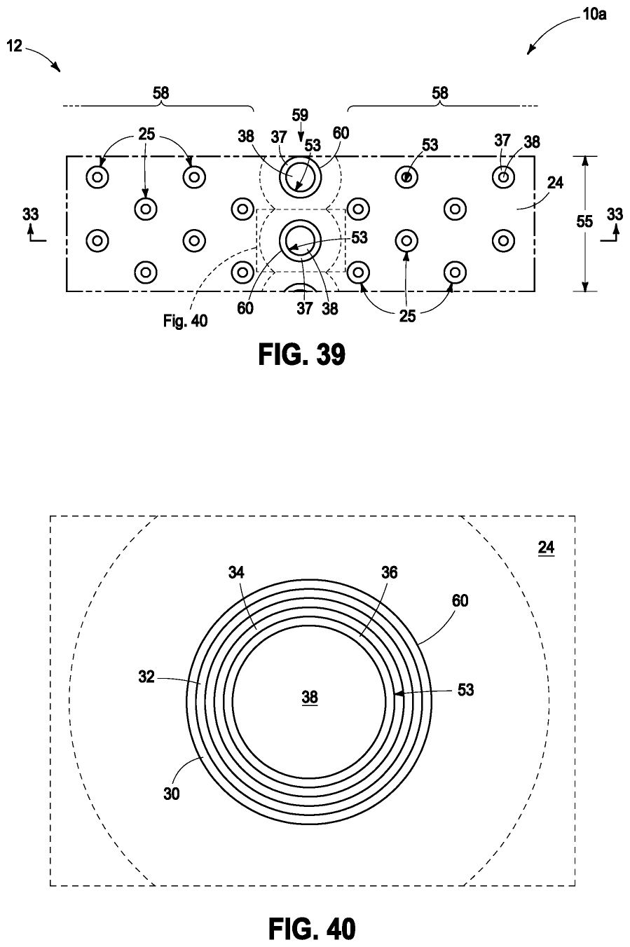

In one embodiment, a memory array (e.g., 12) comprising strings (e.g., 49) of memory cells (e.g., 56) comprises laterally-spaced memory blocks (e.g., 58) individually comprising a vertical stack (e.g., 18) comprising alternating insulative tiers (e.g., 24) and conductive tiers (e.g., 66). Operative channel-material strings (e.g., 53) of memory cells (e.g., 56) extend through the insulative tiers and the conductive tiers in individual of the laterally-spaced memory blocks. An inter-block column (e.g., 61) of dummy channel-material strings (e.g., 53 in FIGS. 39 and 40) extend through the stack longitudinally-along and between immediately-laterally-adjacent of the memory blocks. Any other attribute(s) or aspect(s) as shown and/or described herein with respect to other embodiments may be used.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, modems, processor modules, and communication application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### CONCLUSION

In some embodiments, a method used in forming memory circuitry comprising strings of memory cells comprises forming vertically-alternating tiers of different composition first and second materials. The second material is insulative. The vertically-alternating tiers comprise a stack comprising laterally-spaced memory blocks. An inter-block column of openings is formed through the vertically-alternating tiers longitudinally-along and between immediately-laterally-adjacent of the memory blocks. An intra-block column of openings is formed through the vertically-alternating tiers longitudinally-along and within individual of the memory blocks. Individual of the intra-block columns of openings are entirely within one of the individual memory blocks. A first etchant is flowed into the inter-block columns of openings and into the intra-block columns of openings to etch the first material of the first-material tiers selectively relative to the second-material tiers to form a void-space tier vertically between immediately-vertically-adjacent of the second-material tiers. The void-space tiers are filled with conductive material by flowing the conductive material or one or more precursors thereof through the inter-block columns of openings and through the intra-block columns of openings into the void-space tiers. A second etchant is flowed into the inter-block columns of openings to remove the conductive material from being between the immediately-laterally-adjacent memory blocks in individual of the filled void-space tiers.

In some embodiments, a memory array comprising strings of memory cells comprises laterally-spaced memory blocks individually comprising a vertical stack comprising alternating insulative tiers and conductive tiers. Operative channel-material strings of memory cells extend through the insulative tiers and the conductive tiers in individual of the memory blocks. An intra-block column of structures extends through the vertically-alternating tiers longitudinally-along and within the individual memory blocks. An annular void-space is circumferentially around individual of the structures in individual of the conductive tiers.

In some embodiments, a memory array comprising strings of memory cells comprises laterally-spaced memory blocks individually comprising a vertical stack comprising alternating insulative tiers and conductive tiers. Operative channel-material strings of memory cells extend through the insulative tiers and the conductive tiers in individual of the laterally-spaced memory blocks. An inter-block column of dummy channel-material strings extends through the stack longitudinally-along and between immediately-laterally-adjacent of the memory blocks.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry comprising strings of memory cells, comprising:
forming vertically-alternating tiers of different composition first and second materials, the second material being insulative, the vertically-alternating tiers comprising a stack comprising laterally-spaced memory blocks;
forming an inter-block column of openings through the vertically-alternating tiers longitudinally-along and between immediately-laterally-adjacent of the memory blocks;
forming an intra-block column of openings through the vertically-alternating tiers longitudinally-along and within individual of the memory blocks, individual of the intra-block columns of openings being entirely within one of the individual memory blocks;
flowing a first etchant into the inter-block columns of openings and into the intra-block columns of openings to etch the first material of the first-material tiers selectively relative to the second-material tiers to form a void-space tier vertically between immediately-vertically-adjacent of the second-material tiers;
filling the void-space tiers with conductive material by flowing the conductive material or one or more precursors thereof through the inter-block columns of openings and through the intra-block columns of openings into the void-space tiers; and
flowing a second etchant into the inter-block columns of openings to remove the conductive material from being between the immediately-laterally-adjacent memory blocks in individual of the filled void-space tiers.

2. The method of claim 1 comprising forming the inter-block columns of openings and the intra-block columns of openings simultaneously.

3. The method of claim 1 comprising forming the inter-block columns of openings and the intra-block columns of openings at different times.

4. The method of claim 1 comprising forming the intra-block columns of openings to be laterally-centered within the individual memory blocks.

5. The method of claim 1 comprising:
forming multiple of the intra-block column of openings through the vertically-alternating tiers longitudinally-along and within the individual memory blocks;
flowing the first etchant into the multiple intra-block columns of openings within the individual memory blocks to etch the first material of the first-material tiers selectively relative to the second-material tiers to form the void-space tier vertically between the immediately-vertically-adjacent second-material tiers; and
filling the void-space tiers with the conductive material by flowing the conductive material or one or more precursors thereof through the multiple intra-block columns of openings within the individual memory blocks into the void-space tiers.

6. The method of claim 5 wherein one of the multiple intra-block columns of openings within the individual memory blocks is laterally-centered therein.

7. The method of claim 5 wherein none of the multiple intra-block columns of openings within the individual memory blocks is laterally-centered therein.

8. The method of claim 1 wherein the intra-block columns of openings are completely masked while flowing the second etchant into the inter-block columns of openings to preclude the second etchant from flowing therein.

9. The method of claim 1 comprising forming channel-material strings of the strings of memory cells before forming the conductive material.

10. The method of claim 1 comprising forming channel-material strings of the strings of memory cells after forming the conductive material.

11. The method of claim 1 wherein, prior to removing the conductive material from being between the immediately-laterally-adjacent memory blocks in the individual filled void-space tiers:
the conductive material is formed in the inter-block columns of openings and in the intra-block columns of openings; and
etching the conductive material from the inter-block columns of openings and from the intra-block columns of openings and to form an annular void-space circumferentially around the inter-block columns of openings and the intra-block columns of openings in individual of the void-space tiers.

12. A memory array comprising strings of memory cells, comprising:
laterally-spaced memory blocks individually comprising a vertical stack comprising alternating insulative tiers and conductive tiers, operative channel-material strings of memory cells extending through the insulative tiers and the conductive tiers in individual of the memory blocks;
an intra-block column of structures extending through the vertically-alternating tiers longitudinally-along and within the individual memory blocks; and
an annular void-space circumferentially around individual of the structures in individual of the conductive tiers.

13. The memory array of claim 12 wherein the structures individually comprise a dummy channel-material string.

14. The memory array of claim 12 wherein the structures do not individually comprise a dummy channel-material string.

15. The memory array of claim 14 wherein the structures individually comprise an insulative pillar.

16. The memory array of claim 14 wherein the structures individually comprise an insulative cylinder surrounding a conductive-material core.

17. The memory array of claim 16 wherein the structures individually comprise an operative through-array-via.

18. The memory array of claim 16 wherein the structures individually comprise a dummy through-array-via.

19. The memory array of claim 12 comprising multiple of said intra-block column of structures within the individual memory blocks.

20. A memory array comprising strings of memory cells, comprising:
laterally-spaced memory blocks individually comprising a vertical stack comprising alternating insulative tiers and conductive tiers, operative channel-material strings of memory cells extending through the insulative tiers and the conductive tiers in individual of the laterally-spaced memory blocks; and
an inter-block column of dummy channel-material strings extending through the stack longitudinally-along and between immediately-laterally-adjacent of the memory blocks.
